(19) United States
(12) Patent Application Publication
(10) Pub. No.: US 2020/0264667 A1
(43) Pub. Date: Aug. 20, 2020

(54) WINDOW ASSEMBLY AND DISPLAY DEVICE INCLUDING THE SAME

(71) Applicant: SAMSUNG DISPLAY CO., LTD., Yongin-si (KR)

(72) Inventor: LULY LEE, Yongin-Si (KR)

(21) Appl. No.: 16/774,514

(22) Filed: Jan. 28, 2020

(30) Foreign Application Priority Data
Feb. 14, 2019 (KR) 10-2019-0016987

(51) Int. Cl. G06F 1/16; G02B 1/16; H01L 27/32

(52) U.S. Cl. CPC G06F 1/1652; G06F 1/1656; G02B 2207/121; G02B 1/16; H01L 27/3244; G06F 1/1626

(57) ABSTRACT

A display device includes a cover window having a bezel area including an opening, a stiffener, and a display panel. The stiffener includes a support portion on the rear surface, an insertion portion protruding from the support portion and inserted in the opening, a first bending portion extending from the support portion and bent at a first angle, and a second bending portion extending from the first bending portion and bent at a second angle. A cover part may be disposed in the insertion portion and of which at least a portion is exposed through the opening at the front surface. The display panel disposed on the rear surface of the cover window and includes at least one pixel configured to provide an image. The second angle is greater than the first angle, and the second angle is 180 degrees.

### CROSS-REFERENCE TO RELATED APPLICATION

This U.S. non-provisional patent application claims priority under 35 U.S.C. § 119 to Korean Patent Application No. 10-2019-0016987, filed on Feb. 14, 2019, the disclosure of which is incorporated by reference herein.

### BACKGROUND

### 1. Technical Field

The present disclosure herein relates to a window assembly for a display device and a display device including the same, and more particularly, to a window assembly with improved reliability and a display device including the same.

### 2. Discussion of Related Art

A mobile device (e.g., a portable phone) may include a display panel in which pixels are arranged to display an image, and a cover window for protecting the display panel. The display panel may include a liquid crystal display panel or an organic light emitting display panel. A user may view an image displayed on the display panel through the cover window.

The cover window may include various layers to improve durability and to improve fingerprint resistance.

### SUMMARY

At least one embodiment of the present disclosure provide a window assembly for a display device and a display device including the same. The window assembly may be capable of improving durability of a stiffener disposed under a cover window to minimize interference between printed areas of the cover window and to improve reliability.

According to an exemplary embodiment of the inventive concept, a display device includes a cover window which includes a front surface including a transmission area and a bezel area adjacent the transmission area, and a rear surface opposite to the front surface, the bezel area including an opening; a stiffener including a support portion disposed on the rear surface, an insertion portion protruding from the support portion and inserted in the opening, a first bending portion extending from the support portion and bent from the support portion at a first angle, and a second bending portion extending from the first bending portion and bent from the first bending portion at a second angle; and a display panel disposed on the rear surface of the cover window and including at least one pixel configured to provide an image to the transmission area. The second angle is greater than the first angle, and the second angle is 180 degrees.

In an embodiment, a cover part is disposed in the insertion portion and of which at least a portion is exposed through the opening at the front surface.

In an embodiment, the first angle is 90 degrees or less.

In an embodiment, the first bending portion includes a first portion bent from the support portion, a second portion bent from the first portion, and an additional portion connected to at least one of the first portion and the second portion. A moment of inertia i of the first bending portion equal bh³/12, where b is a thickness of the first bending portion in a thickness direction, and h is a height of the first bending portion in a height direction perpendicular to the thickness direction.

In an embodiment, the additional portion extends from the first portion and is bent from the first portion, and the thickness b of the first bending portion is a sum of thicknesses of the first portion and the additional portion in the thickness direction.

In an embodiment, an angle at which the additional portion is bent from the first portion is 180 degrees.

In an embodiment, the additional portion extends from the second portion and is bent from the second portion, and the height h of the first bending portion is a height of the additional portion in the height direction.

In an embodiment, an angle at which the additional portion is bent from the second portion is 90 degrees.

In an embodiment, the second bending portion includes an inner surface adjacent the first bending portion, and an outer surface opposite to the inner surface. At least a portion of the inner surface may be in contact with the first bending portion.

In an embodiment, the second bending portion is bent from the first bending portion in a direction away from the cover window.

In an embodiment, the second bending portion is bent from the first bending portion in a direction toward the cover window.

In an embodiment, the display device further includes a bonding portion disposed between the cover window and the first bending portion, where the bonding portion is bent at the first angle.

In an embodiment, the stiffener further includes a third bending portion extending from the second bending portion and bent from the second bending portion at a third angle, where the third angle is equal to the second angle.

In an embodiment, the cover part has a mesh shape.

In an embodiment, the insertion portion defines a receiver hole exposing a portion of the cover part, and the receiver hole has a closed-line shape.

According to an exemplary embodiment of the inventive concept, a window assembly includes: a cover window which includes a front surface including a transmission area and a bezel area adjacent the transmission area and a rear surface opposite to the front surface, the bezel area including an opening; a stiffener including a support portion disposed on the rear surface, an insertion portion protruding from the support portion and inserted in the opening, a first bending portion extending from the support portion and bent from the support portion at a first angle, and a second bending portion extending from the first bending portion and bent from the first bending portion at a second angle; and a cover part disposed in the insertion portion and of which at least a portion is exposed through the opening at the front surface. The first bending portion includes a first portion bent from the support portion, a second portion bent from the first portion, and an additional portion connected to at least one of the first portion and the second portion. A moment of inertia i equals bh³/12, where b is a thickness of the first bending portion in a thickness direction, and h is a height of the first bending portion in a height direction perpendicular to the thickness direction.

In an embodiment, the additional portion extends from the first portion and is bent from the first portion, and the thickness b of the first bending portion is a sum of thicknesses of the first portion and the additional portion in the thickness direction.

In an embodiment, an angle at which the additional portion is bent from the first portion is 180 degrees.

In an embodiment, the additional portion extends from the second portion is bent from the second portion, and the height h of the first bending portion is a height of the additional portion in the height direction.

In an embodiment, an angle at which the additional portion is bent from the second portion is 90 degrees.

In an embodiment, the second angle is 180 degrees, and the first angle is 90 degrees or less.

According to an exemplary embodiment of the inventive concept, an assembly for supporting a cover window of a display device includes: a support portion including an opening; an insertion portion protruding from and surrounding the opening; a first portion extending from the support portion and bent from the support portion at an acute angle; a second portion extending from the first portion and bent from the first portion at an obtuse angle; a third portion extending from the second portion and bent from the second portion to contact a side of the second portion; a fourth portion extending from the third portion and bent from the third portion at an acute angle; and a fifth portion extending from the fourth portion and bent from the fourth portion at an obtuse angle.

In an embodiment, the assembly further includes a mesh filling the opening.

In an embodiment, the assembly further includes an anti-electrostatic device connected to the fifth portion.

### BRIEF DESCRIPTION OF THE DRAWINGS

The accompanying drawings are included to provide a further understanding of the inventive concepts, and are incorporated in and constitute a part of this specification. The drawings illustrate exemplary embodiments of the inventive concepts and, together with the description, serve to explain principles of the inventive concepts. In the drawings:

FIG. 1 is a perspective view illustrating a display device according to an exemplary embodiment of the inventive concept;

FIG. 2 is an exploded perspective view illustrating a display device according to an exemplary embodiment of the inventive concept;

FIG. 3A is a plan view illustrating a display panel according to an exemplary embodiment of the inventive concept;

FIG. 3B is an equivalent circuit diagram of a pixel of the display panel according to an exemplary embodiment of the inventive concept;

FIG. 4A is a perspective view illustrating a component of a window assembly according to an exemplary embodiment of the inventive concept;

FIG. 4B is a plan view illustrating a partial area of a display device according to an exemplary embodiment of the inventive concept;

FIG. 4C is a cross-sectional view illustrating a window assembly according to an exemplary embodiment of the inventive concept;

FIG. 4D is a cross-sectional view illustrating a window assembly according to an exemplary embodiment of the inventive concept;

FIG. 5A is a perspective view illustrating a component of a window assembly according to an exemplary embodiment of the inventive concept;

FIG. 5B is a cross-sectional view illustrating a window assembly according to an exemplary embodiment of the inventive concept;

FIG. 6A is a perspective view illustrating a component of a window assembly according to an exemplary embodiment of the inventive concept;

FIG. 6B is a cross-sectional view taken along a line I-I′ of FIG. 6A;

FIG. 7A is a perspective view illustrating a component of a window assembly according to an exemplary embodiment of the inventive concept;

FIG. 7B is a cross-sectional view taken along a line II-IF of FIG. 7A;

FIG. 8A is a perspective view illustrating a component of a window assembly according to an exemplary embodiment of the inventive concept;

FIG. 8B is a cross-sectional view illustrating a window assembly according to an exemplary embodiment of the inventive concept;

FIG. 9A is a perspective view illustrating a component of a window assembly according to an exemplary embodiment of the inventive concept;

FIG. 9B is a cross-sectional view taken along a line III-III′ of FIG. 9A;

FIG. 10A is a perspective view illustrating a component of a window assembly according to an exemplary embodiment of the inventive concept; and

FIG. 10B is a cross-sectional view taken along a line IV-IV′ of FIG. 10A.

### DETAILED DESCRIPTION OF THE EXEMPLARY EMBODIMENTS

The inventive concepts now will be described more fully hereinafter with reference to the accompanying drawings, in which various embodiments are shown. The inventive concepts may, however, be embodied in many different forms, and should not be construed as limited to the embodiments set forth herein. Rather, these embodiments are provided so that this disclosure will be thorough and complete, and will fully convey the scopes of the inventive concepts to those skilled in the art. Like reference numerals refer to like elements throughout.

It will be understood that when an element such as a layer, region or substrate is referred to as being “on” another element, it can be directly on the other element or intervening elements may be present. In contrast, the term “directly” means that there are no intervening elements.

As used herein, the singular forms “a,” “an,” and “the” are intended to include the plural forms, including “at least one,” unless the content clearly indicates otherwise. As used herein, the term “and/or” includes any and all combinations of one or more of the associated listed items.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system).

Exemplary embodiments should not be construed as limited to the shapes of regions illustrated herein but are to include deviations in shapes that result, for example, from manufacturing. For example, an etching region illustrated here as a rectangle may have rounded or curved features when manufactured.

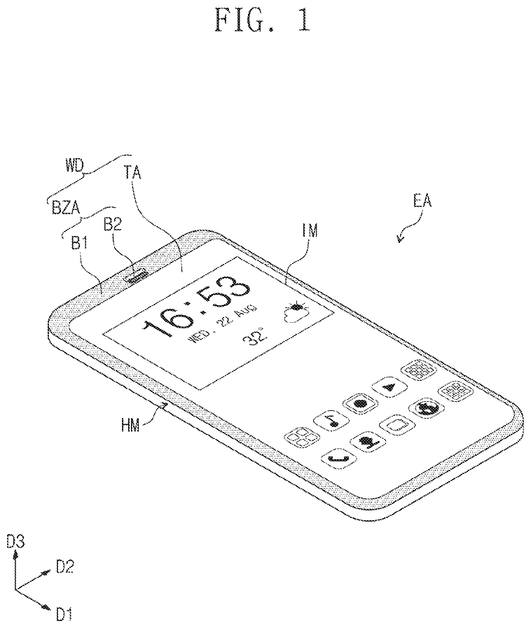

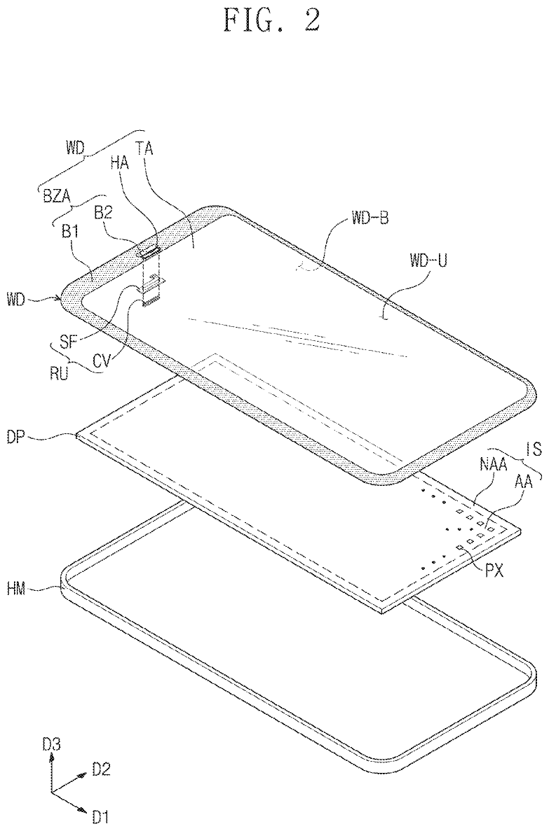

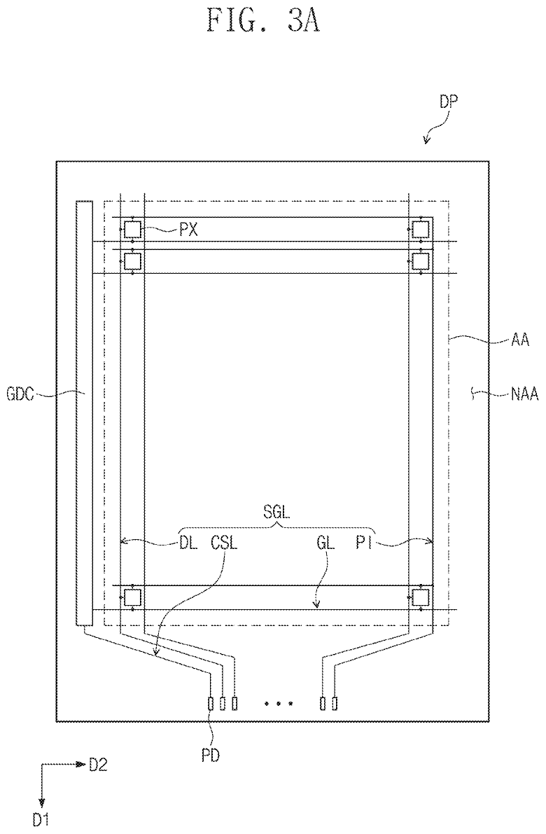

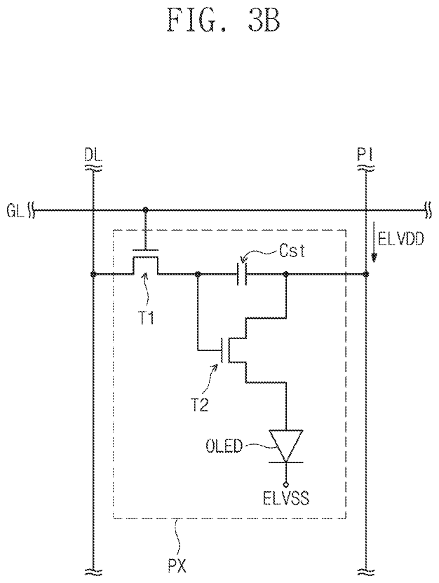

FIG. 1 is a perspective view illustrating a display device according to an exemplary embodiment of the inventive concept. FIG. 2 is an exploded perspective view of the display device according to an exemplary embodiment of the inventive concept. FIG. 3A is a plan view illustrating a display panel according to an exemplary embodiment of the inventive concept that may be used in the display device. FIG. 3B is an equivalent circuit diagram of a pixel of the display panel according to an exemplary embodiment of the inventive concept.

Referring to FIGS. 1 and 2, a display device EA displays an image IM on a plane, defined by first and second directions D1 and D2, in a third direction D3. The display device EA includes a cover window WD, a receiver unit RU, a display panel DP, and a housing member HM (e.g., a back cover plate).

The cover window WD includes a front surface WD-U exposed to the outside and a rear (or back) surface WD-B opposite to the front surface WD-U. The image IM displayed on the display panel DP may be visible to the outside through the front surface WD-U. The cover window WD is divided into a transmission area TA and a bezel area BZA when viewed in a plan view.

The transmission area TA may transmit light incident thereto. The transmission area TA may have a shape corresponding to a shape of an active area AA of the display panel DP. For example, the transmission area TA may overlap with the whole or at least a portion of the active area AA. The image IM displayed in the active area AA of the display panel DP may be visible to the outside through the transmission area TA.

In an exemplary embodiment, light transmittance of the bezel area BZA is less than light transmittance of the transmission area TA. The bezel area BZA may define a shape of the transmission area TA. The bezel area BZA is adjacent to the transmission area TA and surrounds the transmission area TA in a plan view. The bezel area BZA may have a predetermined color. In an embodiment, the bezel area BZA covers a peripheral area NAA of the display panel DP to prevent the peripheral area NAA from being visible to the outside.

In an embodiment, the bezel area BZA includes a first area B1 and a second area B2. The first area B1 surrounds the second area B2 when viewed in a plan view. The first area B1 and the second area B2 may have the same color. A material for blocking light may be printed or deposited in the first area B1.

In an embodiment, light transmittance of the second area B2 is higher than light transmittance of the first area B1. For example, the second area B2 may be printed or deposited with a material having a light transmittance higher than that of the material printed or deposited in the first area B1. In FIGS. 1 and 2, the first and second areas B1 and B2 having different light transmittances are shown in different shades for the purpose of ease and convenience in description. However, the first and second areas B1 and B2 may be visible to a user in substantially the same color. When the second area B2 has the same color as the first area B1, a boundary between the first and second areas B1 and B2 may not be visible to a user.

The cover window WD may be optically transparent. For example, the cover window WD may include glass or plastic. The cover window WD may have a single-layered or multi-layered structure. For example, the cover window WD may have a stack structure including a plurality of plastic films coupled to each other by an adhesive or may have a stack structure which includes a glass substrate and a plastic film coupled to each other by an adhesive.

In an exemplary embodiment, an opening HA is present in the cover window WD. The opening HA may be a space penetrating the cover window WD in the third direction D3. For example, the opening HA may be a through-hole of the cover window WD. The opening HA may be a space in which the receiver unit RU to be described later in detail is inserted. The opening HA may overlap with the first area B1. In addition, the opening HA may be spaced apart from the second area B2.

In an embodiment, the receiver unit RU includes a stiffener SF and a cover part CV. For example, the stiffener SF may be a physical structure that gives support to the cover window WD to reduce the chances of the cover window WD bending or cracking. The physical structure may prevent the cover window WD from deforming when pressure is applied to the cover window WD. In an embodiment, the receiver unit RU is disposed on the rear surface WD-B of the cover window WD. In an embodiment, the receiver unit RU overlaps with the bezel area BZA of the cover window WD and is spaced apart from the transmission area TA. The stiffener SF and the cover part CV will be described later in detail.

In an embodiment, the display device EA further includes one or more sensing units (not shown). The sensing units may be disposed on the rear surface WD-B of the cover window WD. In an embodiment, the sensing units overlap with the second area B2 and do not overlap with the transmission area TA.

The sensing units may include a light source unit and/or an iris camera. For example, the light source unit may be an infrared light emitting diode (IR LED), and the iris camera may obtain an image of a user's eye by using red near-infrared emitted from the IR LED as a light source to recognize iris information. However, embodiments of the inventive concepts are not limited thereto. In certain embodiments, the sensing units may include a light source unit, a pilot lamp, an illumination sensor, and/or a proximity sensor. The sensing units may receive a user's iris information, a proximity degree of a user, and/or the amount of external light through the second area B2.

The second area B2 may be an area that overlaps with the sensing units (not shown). Thus, the sensing units may receive information using a user's biometric information and/or light, transmitted through the second area B2. Since the light transmittance of the second area B2 is higher than that of the first area B1, it is possible to effectively secure the amount of incident light transmitted to the sensing units overlapping with the second area B2.

In FIGS. 1 and 2, the second area B2 is illustrated in only a partial area adjacent to the opening HA. However, embodiments of the inventive concepts are not limited thereto. A shape and a size of the second area B2 overlapping with the sensing units may be variously modified.

Referring to FIGS. 3A and 3B, the display panel DP according to an exemplary embodiment of the inventive concept includes the active area AA and the peripheral area NAA. In the present embodiment, the peripheral area NAA has a closed-line shape surrounding the active area AA.

The display panel DP includes a driving circuit GDC, a plurality of signal lines SGL, a plurality of pixels PX, and a plurality of pads PD. The pixels PX may be disposed in the active area AA. Each of the pixels PX may include an organic light emitting element and a pixel driving circuit connected to the organic light emitting element.

The driving circuit GDC may include a scan (or gate) driving circuit. The scan driving circuit may generate a plurality of scan signals and may sequentially output the scan signals to a plurality of scan lines GL to be described below. The scan driving circuit may further output other control signals to the pixel driving circuits of the pixels PX. The driving circuit GDC may be formed by the same processes as the pixel driving circuits of the pixels PX.

The signal lines SGL may include scan (or gate) lines GL, data (or source) lines DL, power lines PI, and a control signal line CSL. Each of the scan lines GL may be connected to corresponding ones of the pixels PX, and each of the data lines DL may be connected to corresponding ones of the pixels PX. The power lines PI may be connected to the pixels PX. The control signal line CSL may provide control signals to the scan driving circuit.

The signal lines SGL may be connected to a circuit board (not shown). The signal lines SGL may be connected to a timing control circuit mounted on the circuit board in the form of an integrated chip. However, embodiments of the inventive concepts are not limited thereto. In another embodiment, the integrated chip is disposed in the peripheral area NAA so as to be connected to the signal lines SGL.

The pads PD may be connected to corresponding signal lines SGL and may be connected to a flexible circuit board (not shown) on which driving chips (not shown) are mounted. Each of the signal lines SGL may transmit/receive an electrical signal to/from the flexible circuit board through a corresponding one of the pads PD.

FIG. 3B illustrates one scan line GL, one data line DL, one power line PI, and one pixel PX connected to the lines GL, DL and PI. However, the configuration of the pixel PX is not limited thereto but may be variously modified.

The pixel PX includes a first transistor (or a switching transistor) T1, a second transistor (or a driving transistor) T2 and a capacitor Cst which constitute the pixel driving circuit for driving an organic light emitting element OLED. The second transistor T2 may be provided with a first power source voltage ELVDD through the power line PI, and the organic light emitting element OLED may be provided with a second power source voltage ELVSS. In an embodiment, the second power source voltage ELVSS is lower than the first power source voltage ELVDD.

The first transistor T1 may output a data signal, applied to the data line DL, in response to a scan signal applied to the scan line GL. The capacitor Cst may be charged with a voltage corresponding to the data signal received from the first transistor T1. The second transistor T2 is connected to the organic light emitting element OLED. The second transistor T2 may control a driving current, flowing through the organic light emitting element OLED, in response to the amount of charges stored in the capacitor Cst.

The equivalent circuit is illustrated as an example of the pixel PX, and embodiments of the inventive concepts are not limited thereto. The pixel PX may further include a plurality of transistors and/or may include two or more capacitors. In another embodiment, the organic light emitting element OLED is connected between the power line PI and the second transistor T2.

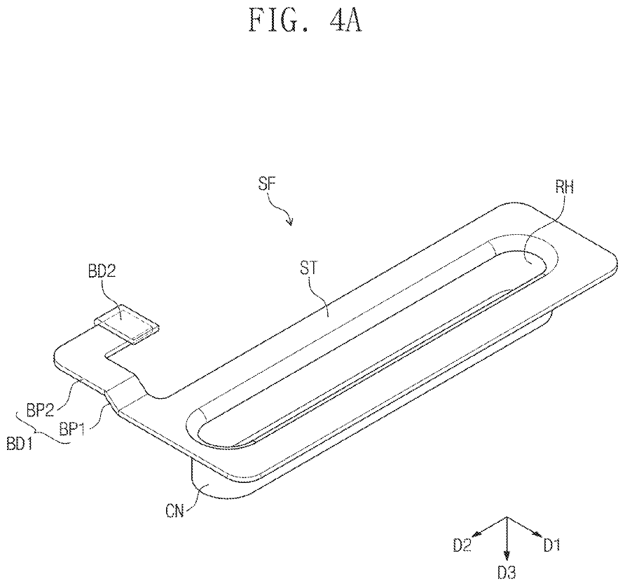

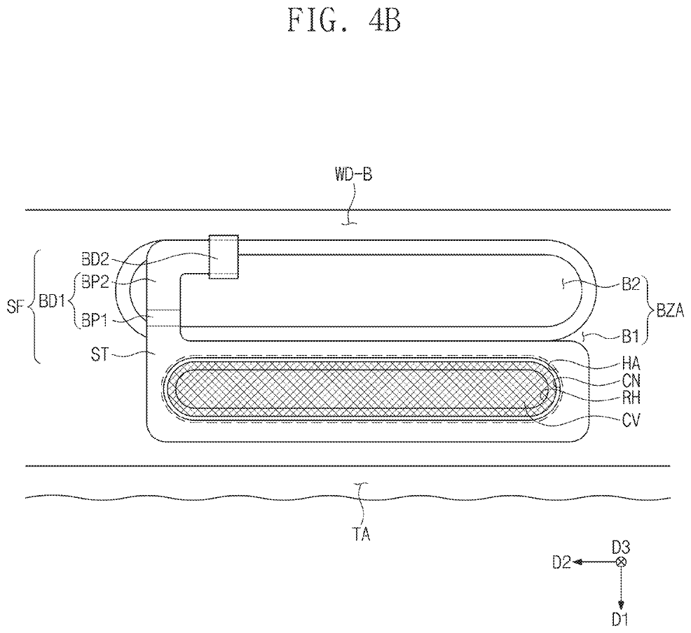

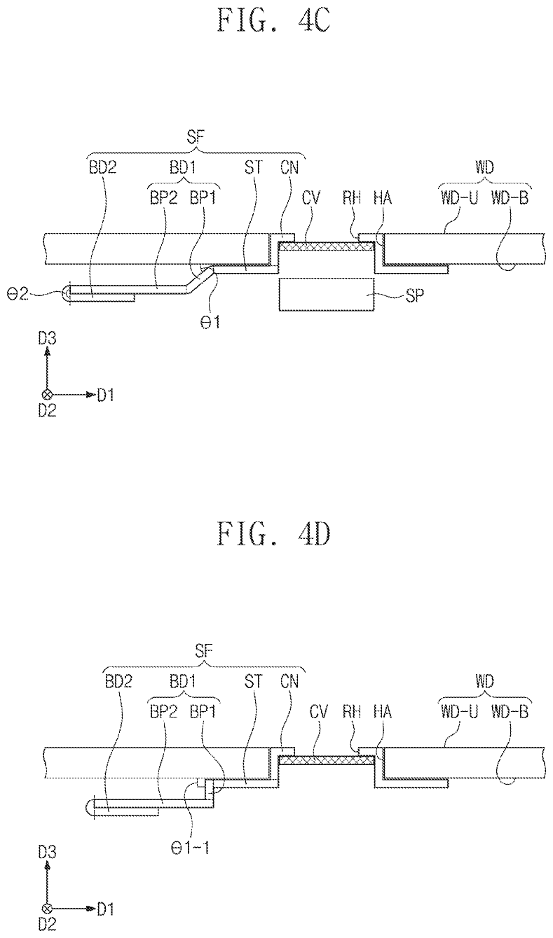

Even though not shown in the drawings, the display device EA according to an embodiment may further include an electronic module. The electronic module may include at least one of various functional modules for operating the display device EA. The electronic module may be electrically connected to the display panel DP through, e.g., a connector. For example, the electronic module may include a camera, a sensor for sensing light or heat, or a speaker SP as illustrated in FIG. 4C.

Referring again to FIG. 1, the housing member HM is disposed under the display panel DP. The housing member HM and the cover window WD may be coupled to each other to constitute an exterior of the display device EA. The housing member HM may be formed of a material having relatively high rigidity. For example, the housing member HM may include a plurality of frames and/or plates, which are formed of glass, plastic, and/or a metal. The housing member HM may provide a receiving space. The display panel DP and the electronic module may be received in the receiving space and thus may be protected from an external impact.

Even though not shown in the drawings, the housing member HM may further include an anti-electrostatic part including a metal material. In an embodiment, the anti-electrostatic part is in contact with at least a portion of the stiffener SF. Thus, static electricity inputted from the outside through the cover part CV may be effectively discharged to the outside of the display device EA. As a result, reliability of the display device EA may be improved.

FIG. 4A is a perspective view illustrating a component of a window assembly according to an exemplary embodiment of the inventive concept. FIG. 4B is a plan view illustrating a partial area of a display device according to an exemplary embodiment of the inventive concept. FIG. 4C is a cross-sectional view illustrating a window assembly according to an exemplary embodiment of the inventive concept. FIG. 4D is a cross-sectional view illustrating a window assembly according to an exemplary embodiment of the inventive concept.

Referring to FIGS. 4A to 4C, the stiffener SF according to an exemplary embodiment includes a support portion ST, an insertion portion CN, a first bending portion BD1, and a second bending portion BD2. The support portion ST, the insertion portion CN, the first bending portion BD1, and the second bending portion BD2 may be made of plastic or metal as an example. In an exemplary embodiment, the support portion ST, the first bending portion BD1, and the second bending portion BD2 are integrally formed.

The support portion ST may be disposed on the rear surface WD-B of the cover window WD. In an embodiment, the support portion ST overlaps with the first area B1 of the cover window WD. In an embodiment, the support portion ST does not overlap the transmission area TA. The support portion ST may be in contact with the rear surface WD-B of the cover window WD.

In an embodiment, the insertion portion CN protrudes from the support portion ST in the third direction D3 and is inserted in the opening HA defined in the cover window WD. The opening HA may be a through-hole that passes completely through the cover window WD. A receiver hole RH is defined in the insertion portion CN. The receiver hole RH may be defined as a space surrounded by the insertion portion CN. Thus, the receiver hole RH may have a closed-line shape. The receiver hole RH may be a through-hole that passes completely through the support section ST. In an embodiment, the receiver hole RH is a space overlapping with a sensing unit such as a speaker SP of an electronic module included in the display device EA. The receiver hole RH may also overlap with other types of sensing units such as those described above over herein.

In an embodiment, the cover part CV is disposed in the insertion portion CN. The cover port CV may be in contact with inner edges of the insertion portion CN. The cover part CV may overlap with the receiver hole RH. In an embodiment, the cover part CV has a mesh shape. A sound provided from the speaker SP may be easily transmitted to the outside through the cover part CV. The cover part CV may be bonded to the insertion portion CN by at least one of welding, an adhesive, or a tape.

The first bending portion BD1 extends from the support portion ST. The first bending portion BD1 may overlap with a portion of the second area B2. In an embodiment, the first bending portion BD1 is bent from the support portion ST at a predetermined bending angle.

In an embodiment, the first bending portion BD1 includes a first portion BP1 and a second portion BP2. The first portion BP1 extends from the support portion ST and is bent from the support portion ST at a first angle θ1. The first angle θ1 may be defined as an angle between the rear surface WD-B of the cover window WD and the first portion BP1. In an embodiment, the first portion BP1 has a rectangular shape, a cuboid shape, or a parallelepiped shape.

The second portion BP2 extends from the first portion BP1. The second portion BP2 may extend in the first direction D1 and may extend in the second direction D2. For example, the second portion BP2 may have a “¬”-shape when viewed in a plan view. For example, the second portion BP2 could include an L shaped a curved L shaped element. The second portion BP2 may be bent from the first portion BP1 at an angle equal to the first angle θ1.

In an embodiment, the first angle θ1 is +90 degrees or less (or about +90 degrees or approximately +90 degrees). For example, the first angle θ1 between the rear surface WD-B and the first portion BP1 bent from the support portion ST may be an acute angle. When the angle θ1 between the rear surface WD-B of the cover window WD is acute, the angle between the second portion BP2 and the first portion BP1 may be obtuse. When the angle θ1 between the rear surface WD-B of the cover window WD is acute, the angle between the first portion BP1 and the support portion ST may be obtuse.

In the present specification, when a component is bent in a direction away from the rear surface WD-B of the cover window WD, a bending angle of the component may be represented by “+”. On the contrary, when a component is bent in a direction toward the rear surface WD-B of the cover window WD, a bending angle of the component may be represented by “−”.

The second bending portion BD2 extends from the first bending portion BD1. In an embodiment, the second bending portion BD2 overlaps with a portion of the second area B2. The second bending portion BD2 may be bent from the first bending portion BD1 at a predetermined bending angle.

In an embodiment, the second bending portion BD2 is bent from the first bending portion BD1 at a second angle θ2. The second angle θ2 may be defined as an angle formed by the first bending portion BD1 and the second bending portion BD2.

In an embodiment, the second angle θ2 is +180 degrees (or about +180 degrees or approximately +180 degrees). Thus, in an exemplary embodiment, an inner surface of the second bending portion BD2, which is adjacent to the first bending portion BD1, is in contact with the first bending portion BD1. In this embodiment, an outer surface of the second bending portion BD2, which is opposite to the inner surface, is not in contact with the first bending portion BD1. In an exemplary embodiment, the second angle θ2 is slightly less than +180 degrees (e.g., +178 degrees, +179 degrees, etc.) so that the inner surface of the second bending portion BD2, which is adjacent to the first bending portion BD1, is not in direct contact with the first bending portion BD1.

In an exemplary embodiment, the second bending portion BD2 is connected to the anti-electrostatic part included in the housing member HM (see FIG. 2). The anti-electrostatic part may be an antistatic device that reduces, dampens, or inhibits electrostatic discharge. According to an exemplary embodiment of the inventive concept, since the second bending portion BD2 is connected to the anti-electrostatic part, static electricity inputted from the outside through the cover part CV may be effectively discharged to the outside of the display device EA. As a result, reliability of the display device EA may be improved.

In addition, the first bending portion BD1 and the second bending portion BD2 may be bent in the direction away from the rear surface WD-B of the cover window WD, and thus it is possible to prevent at least one of the first and second bending portions BD1 and BD2 from interfering with the cover window WD when an impact occurs. For example, at least one of the bending portions BD1 and BD2 may be bent a sufficient distance away from the cover window WD to prevent contact with the WD window during the impact that could cause a crack.

Referring to FIG. 4D, in an exemplary embodiment, the first portion BP1 is bent from the support portion ST at a first angle θ1-1, and the second portion BP2 is bent from the first portion BP1 at an angle equal to the first angle θ1-1.

In an embodiment, the first angle θ1-1 is +90 degrees (or about +90 degrees or approximately +90 degrees). For example, the first angle θ1-1 between the rear surface WD-B and the first portion BP1 bent from the support portion ST may be a right angle.

Since the stiffener SF according to an exemplary embodiment of the inventive concept includes at least one bent portion, plastic deformation may occur by external force or a weight of the stiffener SF.

For example, since the first portion BP1 is bent from the support portion ST at the first angle θ1 or θ1-1 and the second portion BP2 is bent from the first portion BP1 at the angle equal to the first angle θ1 or θ1-1, the second portion BP2 may be spaced apart from the rear surface WD-B and a space may be defined between the second portion BP2 and the cover window WD.

At this time, a moment of inertia i of the second portion BP2 may act. The moment of inertia i may be defined as a property that the second portion BP2 resists deformation when bending force is applied to the second portion BP2 by external force or the weight of the stiffener SF. Thus, rigidity of the stiffener SF may increase as the moment of inertia i increases.

The moment of inertia i may satisfy the following Equation 1.

i=bh³/12 [Equation 1]

Here, ‘b’ denotes a thickness of the first bending portion BD1 in a thickness direction (i.e., the first direction D1), and h denotes a height of the first bending portion BD1 in a height direction (i.e., the third direction D3) perpendicular to the thickness direction.

Referring to Equation 1, the rigidity of the stiffener SF may increase as the thickness of the first bending portion BD1 (i.e., a thickness of the first portion BP1 in the first direction D1) increases. In addition, the rigidity of the stiffener SF may increase as the height of the first bending portion BD1 (i.e., a height of the first portion BP1 in the third direction D3) increases.

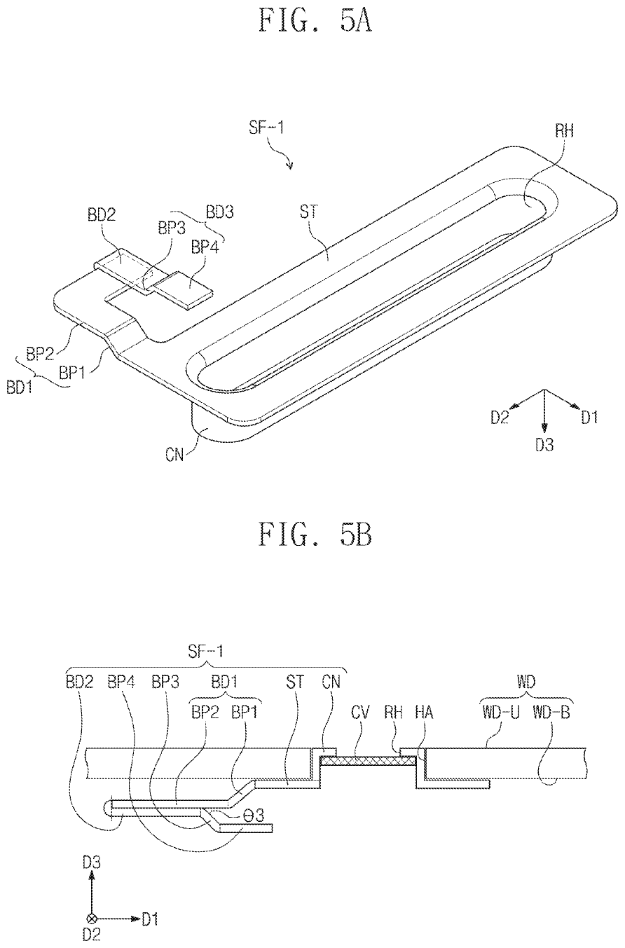

FIG. 5A is a perspective view illustrating a component of a window assembly according to an exemplary embodiment of the inventive concept. FIG. 5B is a cross-sectional view illustrating a window assembly according to an exemplary embodiment of the inventive concept. In the present embodiment, the same/similar components as in the embodiments of FIGS. 1 to 4D will be indicated by the same/similar reference designators, and the descriptions to the same components and features as in the embodiments of FIGS. 1 to 4D will be omitted.

A stiffener SF-1 according to an exemplary embodiment of the inventive concept includes the support portion ST, the insertion portion CN, the first bending portion BD1, the second bending portion BD2, and a third bending portion BD3. In an exemplary embodiment, support portion ST, the insertion portion CN, the first bending portion BD1, the second bending portion BD2, and the third bending portion BD3 are integrally formed.

The third bending portion BD3 extends from the second bending portion BD2 in the first direction D1. In an embodiment, the third bending portion BD3 overlaps with a portion of the second area B2. The third bending portion BD3 is bent from the second bending portion BD2 at a predetermined bending angle.

In an embodiment, the third bending portion BD3 includes a third portion BP3 and a fourth portion BP4. The third portion BP3 extends from the second bending portion BD2 and may be bent from the second bending portion BD2 at a third angle θ3. The third angle θ3 may be equal to an angle formed by the support portion ST and the first bending portion BD1. In an exemplary embodiment, the third angle θ3 is the same as or similar to the angle formed between the rear surface WD-B and the first portion BP1. Thus, the fourth portion BP4 may be parallel to the support portion ST and the second bending portion BD2. In an embodiment, the third angle θ3 is an acute angle.

The fourth portion BP4 may extend from the third portion BP3 in the first direction D1. In an embodiment, the fourth portion BP4 is bent from the third portion BP3 at an angle equal to the third angle θ3. For example, the fourth portion BP4 may be bent so that it is parallel to the second bending portion BD2 or the support portion ST. In an exemplary embodiment, the angle between the second bending portion BD2 and the third portion BP3 is obtuse. In an exemplary embodiment, the angle between the third portion BP3 and the fourth portion BP4 is obtuse.

According to an exemplary embodiment of the inventive concept, the stiffener SF-1 includes the third bending portion BD3 bent in the direction away from the rear surface WD-B of the cover window WD, and thus the stiffener SF-1 may be more easily connected to the anti-electrostatic part of the housing member HM. For example, the anti-electrostatic part may be connected to portion BP4.

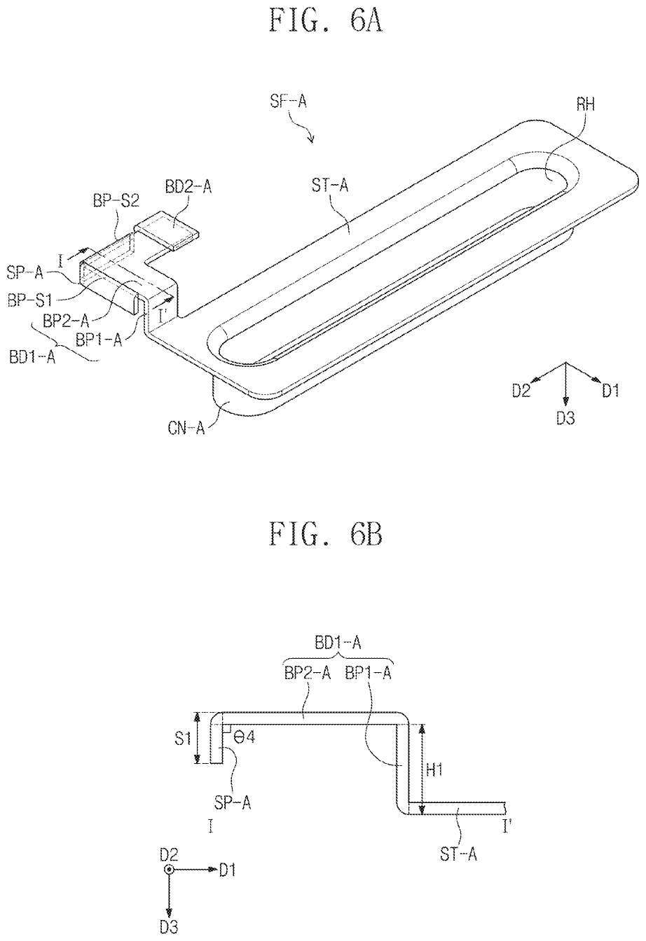

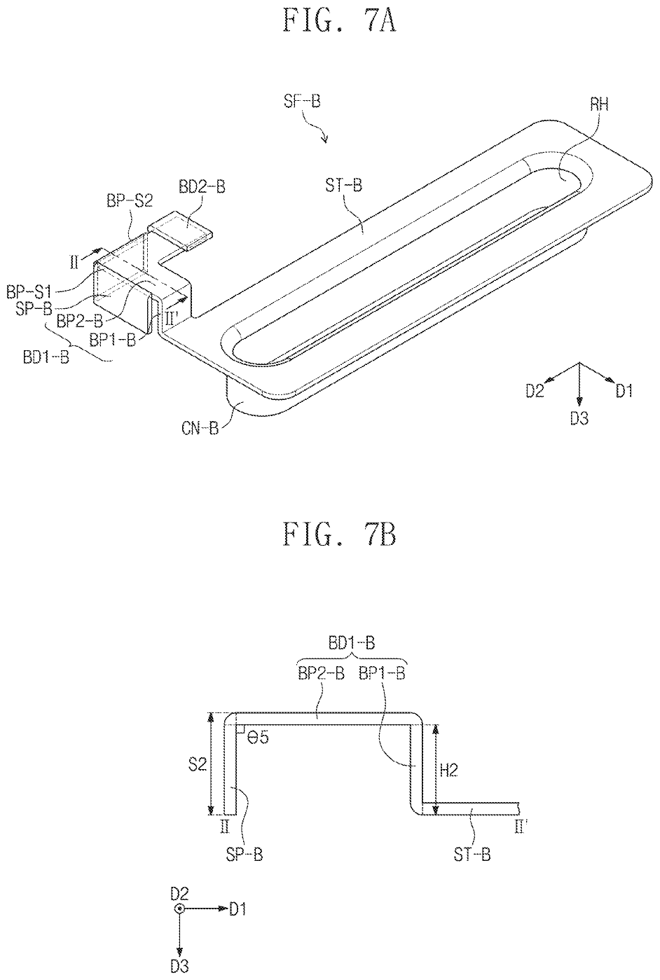

FIG. 6A is a perspective view illustrating a window assembly according to an exemplary embodiment of the inventive concept. FIG. 6B is a cross-sectional view taken along a line I-I′ of FIG. 6A. FIG. 7A is a perspective view illustrating a window assembly according to an exemplary embodiment of the inventive concept. FIG. 7B is a cross-sectional view taken along a line II-IF of FIG. 7A. In the present embodiments, the same/similar components as in the embodiments of FIGS. 1 to 4D will be indicated by the same/similar reference designators, and the descriptions to the same components and features as in the embodiments of FIGS. 1 to 4D will be omitted.

A stiffener SF-A of FIG. 6A, according to an exemplary embodiment includes a support portion ST-A, an insertion portion CN-A, a first bending portion BD1-A, and a second bending portion BD2-A. In an exemplary embodiment, the support portion ST-A, the insertion portion CN-A, the first bending portion BD1-A, and the second bending portion BD2-A are integrally formed.

The support portion ST-A, the insertion portion CN-A and the second bending portion BD2-A of the stiffener SF-A may correspond to the support portion ST, the insertion portion CN and the second bending portion BD2 of the stiffener SF described above with reference to FIGS. 4A to 4C. Hereinafter, the first bending portion BD1-A will be described in detail.

In an embodiment, the first bending portion BD1-A includes a first portion BP1-A, a second portion BP2-A, and an additional portion SP-A. In an exemplary embodiment, the support portion ST-A, the insertion portion CN-A, the first bending portion BD1-A, the second bending portion BD2-A are integrally formed, and the additional portion SP-A are integrally formed. In an embodiment, the additional portion SP-A includes one or more rectangular, cuboid, or parallelepiped shaped elements.

The first portion BP1-A extends from the support portion ST-A and may be bent from the support portion ST-A at an angle of +90 degrees or less. The second portion BP2-A extends from the first portion BP1-A and may be bent from the first portion BP1-A at an angle equal to the angle at which the first portion BP1-A is bent from the support portion ST-A. Thus, the second portion BP2-A may be disposed parallel to the support portion ST-A with the first portion BP1-A interposed therebetween.

The second portion BP2-A may include a first side surface BP-S1 and a second side surface BP-S2. The additional portion SP-A may extend from at least one of the side surfaces of the second portion BP2-A. For example, the additional portion SP-A may extend from the first side surface BP-S1 and may be bent from the first side surface BP-S1 at a fourth angle θ4. In addition, the additional portion SP-A may also extend from the second side surface BP-S2 and may be bent from the second side surface BP-S2 at the fourth angle θ4. For example, one or two flaps may extend downward toward the cover window WD from the second portion BP2-A. For example, each flap may have a rectangular, cuboid, or parallelepiped shape.

Referring to FIG. 6B, the fourth angle θ4 may be −90 degrees (or about −90 degrees or approximately −90 degrees). Thus, the additional portion SP-A may be bent from the side surfaces BP-S1 and BP-S2 in the direction toward the cover window WD (see FIG. 4C). In an embodiment, the fourth angle θ4 is slightly more than −90 degrees (−91, −92, etc.) or slightly less than −90 degrees (e.g., −89, −88).

In an embodiment, a height S1 of the additional portion SP-A is less than a height H1 of the first portion BP1-A.

According to the present embodiment, the first bending portion BD1-A may further include the additional portion SP-A, and thus the height (h) of the parameters of Equation 1 may increase. As a result, rigidity of the stiffener SF-A may be increased. For example, the height (h) of the parameters of Equation 1 may be defined as the height S1 of the additional portion SP-A in the third direction D3. When the additional portion SP-A is not present, a height of the first bending portion BD1-A is a height of the second portion BP2-A in the third direction D3. However, since the additional portion SP-A is added according to the present embodiment, the height S1 of the first bending portion BD1-A may be increased.

According to the present embodiment, the height h may be increased to increase the moment of inertia i, and thus durability of the stiffener SF-A may be improved or enhanced.

FIG. 6A illustrates a plurality of the additional portions SP-A bent from the side surfaces BP-S1 and BP-S2. However, embodiments of the inventive concept are not limited thereto. For example, a single additional portion SP-A may extend from only one of the side surfaces BP-S1 and BP-S2.

Referring to FIGS. 7A and 7B, a stiffener SF-B according to an exemplary embodiment of the inventive concept includes a support portion ST-B, an insertion portion CN-B, a first bending portion BD1-B, and a second bending portion BD2-B.

The support portion ST-B, the insertion portion CN-B and the second bending portion BD2-B of the stiffener SF-B may correspond to the support portion ST-A, the insertion portion CN-A and the second bending portion BD2-A of the stiffener SF-A described above with reference to FIGS. 6A and 6B. Hereinafter, the first bending portion BD1-B will be described in detail.

The first bending portion BD1-B includes a first portion BP1-B, a second portion BP2-B, and an additional portion SP-B.

The first portion BP1-B extends from the support portion ST-B and is bent from the support portion ST-B at an angle of +90 degrees or less. The second portion BP2-B extends from the first portion BP1-B and may be bent from the first portion BP1-B at an angle equal to the angle at which the first portion BP1-B is bent from the support portion ST-B. Thus, the second portion BP2-B may be disposed in parallel to the support portion ST-B with the first portion BP1-B interposed therebetween.

The second portion BP2-B includes a first side surface BP-S1 and a second side surface BP-S2. The additional portion SP-B may extend from at least one of the side surfaces of the second portion BP2-B. For example, the additional portion SP-B may extend from the first side surface BP-S1 and may be bent from the first side surface BP-S1 at a fifth angle θ5. In addition, the additional portion SP-B may also extend from the second side surface BP-S2 and may be bent from the second side surface BP-S2 at the fifth angle θ5.

Referring to FIG. 7B, the fifth angle θ5 is −90 degrees (or about −90 degrees or approximately −90 degrees). Thus, the additional portions SP-B may be bent from the side surfaces BP-S1 and BP-S2 in the direction toward the cover window WD (see FIG. 4C). In an embodiment, the fifth angle θ5 is slightly less than 90 degrees (e.g., 88, 89, etc.) or slightly more than 90 degrees (e.g., −91, −92, etc.).

In an embodiment, a height S2 of the additional portion SP-B is equal to or greater than a height H2 of the first portion BP1-B.

According to the present embodiment, the first bending portion BD1-B further includes the additional portion SP-B, and thus the height h of the parameters of Equation 1 may increase. As a result, rigidity of the stiffener SF-B may be increased. For example, the height (h) of the parameters of Equation 1 may be defined as the height S2 of the additional portion SP-B in the third direction D3, according to the present embodiment. Thus, when the additional portion SP-B is not present, a height of the first bending portion BD1-B is a height of the second portion BP2-B in the third direction D3. However, since the additional portion SP-B is added according to the present embodiment, the height S2 of the first bending portion BD1-B may be increased.

According to the present embodiment, the height h is increased to increase the moment of inertia i, and thus durability of the stiffener SF-B may be improved or enhanced.

FIG. 7A illustrates a plurality of the additional portions SP-B bent from the side surfaces BP-S1 and BP-S2. However, embodiments of the inventive concepts are not limited thereto. For example, a single additional portion SP-B may extend from only one of the side surfaces BP-S1 and BP-S2.

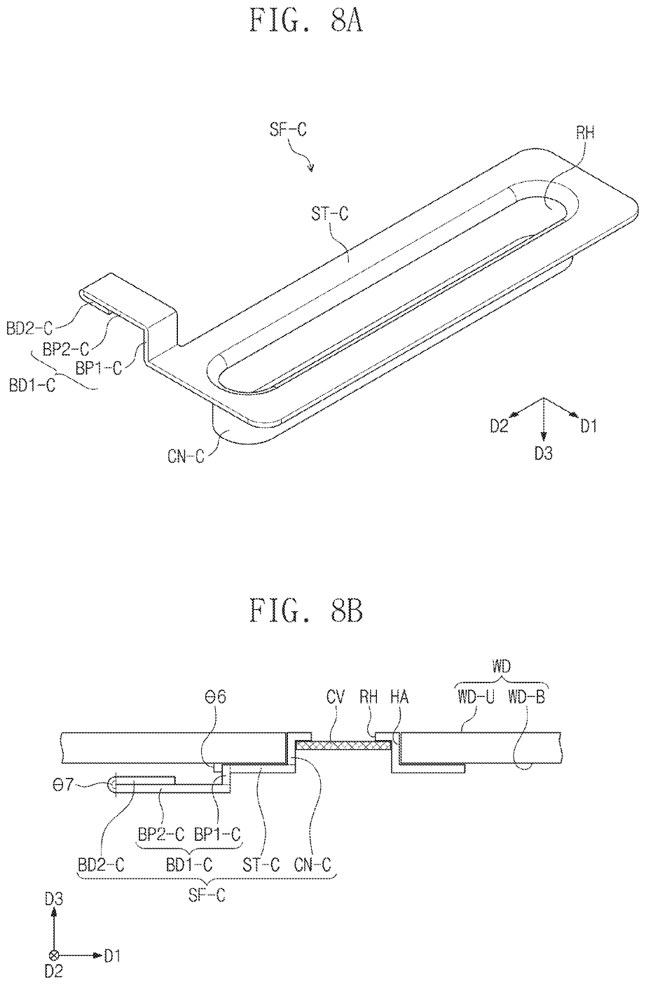

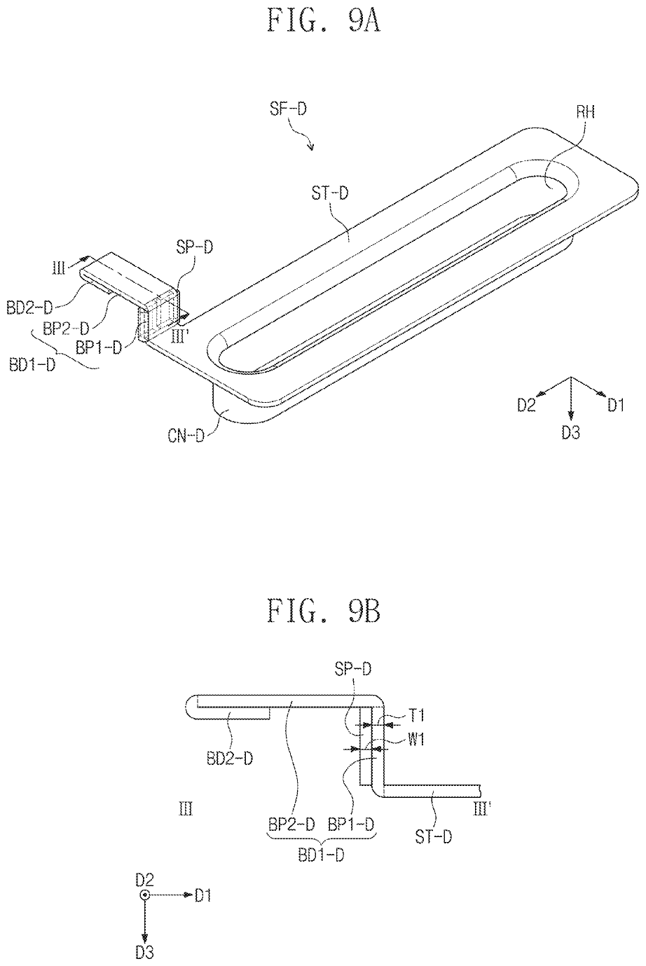

FIG. 8A is a perspective view illustrating a component of a window assembly according to an exemplary embodiment of the inventive concept. FIG. 8B is a cross-sectional view of the window assembly of FIG. 8A according to an embodiment of the inventive concept. FIG. 9A is a perspective view illustrating a component of a window assembly according to an exemplary embodiment of the inventive concept. FIG. 9B is a cross-sectional view taken along a line III-III′ of FIG. 9A. In the present embodiment, the same/similar components as in the embodiments of FIGS. 1 to 4D will be indicated by the same/similar reference designators, and the descriptions to the same components and features as in the embodiments of FIGS. 1 to 4D will be omitted.

Referring to FIGS. 8A and 8B, a stiffener SF-C according to an exemplary embodiment of the inventive concept includes a support portion ST-C, an insertion portion CN-C, a first bending portion BD1-C, and a second bending portion BD2-C.

The support portion ST-C may be disposed on the rear surface WD-B of the cover window WD. In an embodiment, the support portion ST-C overlaps with the first area B1 (see FIG. 4B) of the cover window WD. The support portion ST-C may be in contact with the rear surface WD-B of the cover window WD.

In an embodiment, the insertion portion CN-C protrudes from the support portion ST-C in the third direction D3 and may be inserted in the opening HA defined in the cover window WD. A receiver hole RH is defined in the insertion portion CN-C. The receiver hole RH may be defined as a space surrounded by the insertion portion CN-C. Thus, the receiver hole RH may have a closed-line shape.

The first bending portion BD1-C extends from the support portion ST-C. The first bending portion BD1-C is bent from the support portion ST-C at a predetermined bending angle.

In an embodiment, the first bending portion BD1-C includes a first portion BP1-C and a second portion BP2-C. The first portion BP1-C extends from the support portion ST-C and is bent from the support portion ST-C at a sixth angle θ6.

The second portion BP2-C extends from the first portion BP1-C. The second portion BP2-C may extend in the first direction D1. For example, the second portion BP2-C may have a bar shape when viewed in a plan view. The second portion BP2-C may be bent from the first portion BP1-C at an angle equal to the sixth angle θ6. In an embodiment, the sixth angle θ6 is +90 degrees (or about +90 degrees or approximately +90 degrees). In an alternate embodiment, the sixth angle θ6 is less than +90 degrees.

The second bending portion BD2-C extends from the first bending portion BD1-C. In an embodiment, the second bending portion BD2-C overlaps with a portion of the second area B2. In an exemplary embodiment, the second bending portion BD2-C overlaps with a sensing unit that is disposed in the second area B2. For example, the second bending portion BD2-C may overlap a housing of the sensing unit. The second bending portion BD2-C is bent from the first bending portion BD1-C at a predetermined bending angle.

In an embodiment, the second bending portion BD2-C is bent from the first bending portion BD1-C at a seventh angle θ7. The seventh angle θ7 may be defined as an angle formed by the first bending portion BD1-C and the second bending portion BD2-C.

In an embodiment, the seventh angle θ7 is −180 degrees (or about −180 degrees or approximately −180 degrees). Thus, in an exemplary embodiment, an inner surface of the second bending portion BD2-C, which is adjacent to the first bending portion BD1-C, is in contact with the first bending portion BD1-C. In this embodiment, an outer surface of the second bending portion BD2-C, which is opposite to the inner surface, is not in contact with the first bending portion BD1-C. The outer surface of the second bending portion BD2-C may be closer to the rear surface WD-B of the cover window WD than the inner surface of the second bending portion BD2-C. In an exemplary embodiment, the seventh angle θ7 is slightly less than −180 degrees (e.g., 178, 179, etc.) so that the inner surface of the surface of the second bending portion BD2-C does not contact the first bending portion BD1-C.

In an exemplary embodiment, the second portion BP2-C of the first bending portion BD1-C is connected to the anti-electrostatic part of the housing member HM (see FIG. 2). According to the present embodiment, the number of times of bending of the stiffener SF-C is reduced relative to some of the other previously discussed embodiments to reduce process manufacturing cost and time to manufacture, and thus productivity of manufacturing the stiffener SF-C may be increased.

Referring to FIGS. 9A and 9B, a stiffener SF-D according to an exemplary embodiment includes a support portion ST-D, an insertion portion CN-D, a first bending portion BD1-D, and a second bending portion BD2-D. The support portion ST-D, the insertion portion CN-D and the second bending portion BD2-D of the stiffener SF-D may correspond to the support portion ST-C, the insertion portion CN-C and the second bending portion BD2-C of the stiffener SF-C described above with reference to FIGS. 8A and 8B. Hereinafter, the first bending portion BD1-D will be described in detail.

In an embodiment, the first bending portion BD1-D includes a first portion BP1-D, a second portion BP2-D, and an additional portion SP-D.

The first portion BP1-D extends from the support portion ST-D and may be bent from the support portion ST-D at an angle of +90 degrees. The second portion BP2-D extends from the first portion BP1-D and may be bent from the first portion BP1-D at an angle equal to the angle at which the first portion BP1-D is bent from the support portion ST-D. Thus, the second portion BP2-D may be disposed in parallel to the support portion ST-D with the first portion BP1-D interposed therebetween.

The additional portion SP-D may extend from a side surface of the first portion BP1-D and may be bent from the first portion BP1-D at a predetermined angle. For example, the predetermined angle could be 180 degrees. In an alternate embodiment, the additional portion SP-D is separate portion that is affixed to the first portion BP1-D and the second portion BP2-D. For example, a right side of the separate portion may contact an inner side of the first portion BP1-D and a top side of the separate portion may contact an inner side of the second portion BP2-D. For example, the additional portion SP-D may be affixed to the first portion BP1-D and the second portion BP2-D using an adhesive.

For example, the additional portion SP-D may be bent in a direction toward the second bending portion BD2-D. Thus, a top end of the additional portion SP-D may support the second portion BP2-D of the first bending portion BD1-D.

According to the present embodiment, the first bending portion BD1-D further includes the additional portion SP-D, and thus the thickness b of the parameters of Equation 1 may increase. In an embodiment, the additional portion SP-D is made or includes metal. As a result of adding the additional portion SP-D, rigidity of the stiffener SF-D may be increased. For example, the thickness b of the parameters of Equation 1 may be defined as a sum of a thickness T1 of the first portion BP1-D in the first direction D1 and a thickness W1 of the additional portion SP-D in the first direction D1, in an embodiment. Thus, when the additional portion SP-D is not present, a thickness of the first bending portion BD1-D may be the thickness of the first portion BP1-D in the first direction D1. However, since the additional portion SP-D is added according to the present embodiment, the thickness of the first bending portion BD1-D may be increased.

According to the present embodiment, the thickness b may be increased to increase the moment of inertia i, and thus durability of the stiffener SF-D may be improved or enhanced.

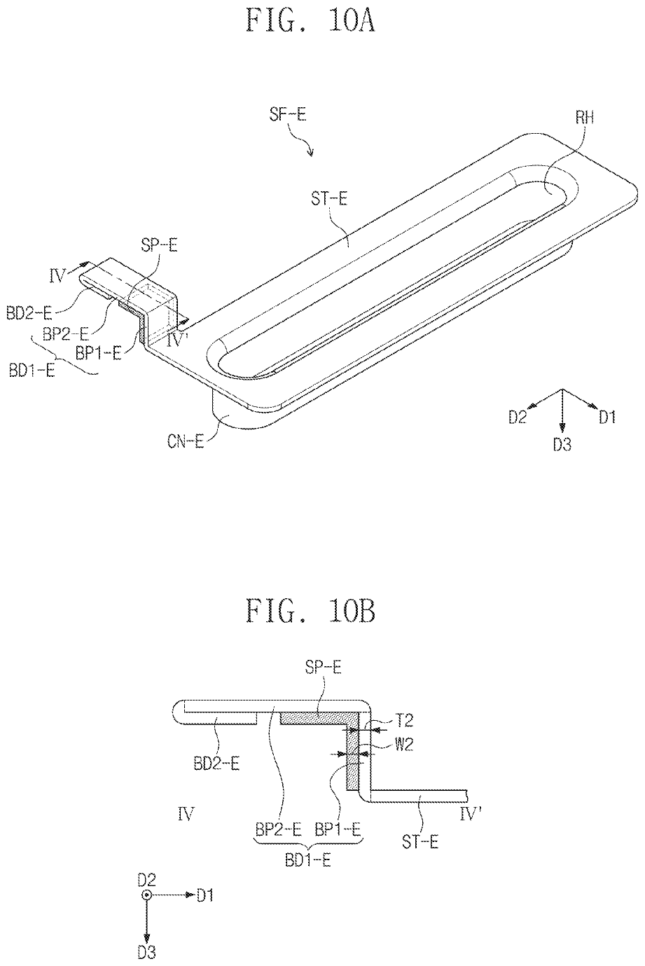

FIG. 10A is a perspective view illustrating a component of a window assembly according to an exemplary embodiment of the inventive concept. FIG. 10B is a cross-sectional view taken along a line IV-IV′ of FIG. 10A. In the present embodiment, the same/similar components as in the embodiments of FIGS. 1 to 4D, 8A and 8B will be indicated by the same/similar reference designators, and the descriptions to the same components and features as in the embodiments of FIGS. 1 to 4D, 8A and 8B will be omitted.

Referring to FIGS. 10A and 10B, a stiffener SF-E according to an exemplary embodiment of the inventive concept includes a support portion ST-E, an insertion portion CN-E, a first bending portion BD1-E, a second bending portion BD2-E, and a bonding portion SP-E. The support portion ST-E, the insertion portion CN-E, the first bending portion BD1-E and the second bending portion BD2-E of the stiffener SF-E may correspond to the support portion ST-C, the insertion portion CN-C, the first bending portion BD1-C and the second bending portion BD2-C of the stiffener SF-C described above with reference to FIGS. 8A and 8B. Hereinafter, the bonding portion SP-E will be described in detail.

The bonding portion SP-E is disposed between the first bending portion BD1-E and the cover window WD (see FIG. 4C). For example, the bonding portion SP-E may be in contact with a portion of a surface, facing the rear surface WD-B, of a second portion BP2-E of the first bending portion BD1-E and a surface of a first portion BP1-E extending from the portion of the surface of the second portion BP2-E. Thus, the bonding portion SP-E may support the first bending portion BD1-E to provide the stiffener SF-E with improved durability. For example, the bonding portion SP-E may include a first bonding portion having a right surface that contacts the inner side of the first portion BP1-E and a second bonding portion having an upper surface that contacts the inner side of the second portion BP2-E. The angle between the first and second bonding portions may be the same as or similar to the angle between the first portion BP1-E and the second portion BP2-E. For example, the bonding portion SP-E may be L shaped. In an embodiment, the bonding portion BD1-E is integrally formed from the first and second bonding portions. In an alternate embodiment, the first and second bonding portions are separate and distinct portions.

In an embodiment, the bonding portion SP-E is made from or includes metal. However, embodiments of the inventive concept are not limited thereto. In a certain embodiment, the bonding portion SP-E may be formed by an insert injection method. For example, the bonding portion SP-E could be formed of plastic.

According to the present embodiment, since the bonding portion SP-E is added, the thickness b and the height h of the parameters of Equation 1 may increase. As a result, rigidity of the stiffener SF-E may be increased.

In a display device according to exemplary embodiments of the inventive concept, the durability of a stiffener may be improved or enhanced by increasing the moment of inertia of the stiffener disposed on the rear surface of the cover window. As a result, the reliability of the display device may be improved.

While the inventive concept has been described with reference to exemplary embodiments thereof, it will be apparent to those skilled in the art that various changes and modifications may be made without departing from the spirit and scope of the inventive concept. Therefore, it should be understood that the above embodiments are not limiting, but illustrative.

What is claimed is:

1. A display device comprising:
a cover window comprising: a front surface including a transmission area and a bezel area adjacent the transmission area; and a rear surface opposite to the front surface, the bezel area comprising an opening;
a stiffener comprising: a support portion disposed on the rear surface; an insertion portion protruding from the support portion and inserted in the opening; a first bending portion extending from the support portion and bent from the support portion at a first angle; and a second bending portion extending from the first bending portion and bent from the first bending portion at a second angle; and
a display panel disposed on the rear surface of the cover window and comprising at least one pixel configured to provide an image to the transmission area,
wherein the second angle is greater than the first angle, and
wherein the second angle is 180 degrees.

2. The display device of claim 1, wherein the first angle is 90 degrees or less.

3. The display device of claim 1, wherein the first bending portion comprises: a first portion bent from the support portion; a second portion bent from the first portion; and an additional portion connected to at least one of the first portion and the second portion,
wherein a moment of inertia i of the first bending portion equals bh³/12, where b is a thickness of the first bending portion in a thickness direction, and h is a height of the first bending portion in a height direction perpendicular to the thickness direction.

4. The display device of claim 3, wherein the additional portion extends from the first portion and is bent from the first portion, and
wherein the thickness b of the first bending portion is a sum of thicknesses of the first portion and the additional portion in the thickness direction.

5. The display device of claim 4, wherein an angle at which the additional portion is bent from the first portion is 180 degrees.

6. The display device of claim 3, wherein the additional portion extends from the second portion and is bent from the second portion, and
wherein the height h of the first bending portion is a height of the additional portion in the height direction.

7. The display device of claim 6, wherein an angle at which the additional portion is bent from the second portion is 90 degrees.

8. The display device of claim 1, wherein the second bending portion includes: an inner surface adjacent the first bending portion; and an outer surface opposite to the inner surface, and
wherein at least a portion of the inner surface is in contact with the first bending portion.

9. The display device of claim 8, wherein the second bending portion is bent from the first bending portion in a direction away from the cover window.

10. The display device of claim 8, wherein the second bending portion is bent from the first bending portion in a direction toward the cover window.

11. The display device of claim 8, further comprising:
a bonding portion disposed between the cover window and the first bending portion,
wherein the bonding portion is bent at the first angle.

12. The display device of claim 1, wherein the stiffener further comprises: a third bending portion extending from the second bending portion and bent from the second bending portion at a third angle, and
wherein the third angle is equal to the first angle.

13. The display device of claim 1, further comprising a cover part disposed in the insertion portion, wherein the cover part has a mesh shape.

14. The display device of claim 13, wherein the insertion portion defines a receiver hole exposing a portion of the cover part, and
wherein the receiver hole has a closed-line shape.

15. A window assembly comprising:
a cover window comprising: a front surface including a transmission area and a bezel area adjacent the transmission area; and a rear surface opposite to the front surface, the bezel area comprising an opening;
a stiffener comprising: a support portion disposed on the rear surface; an insertion portion protruding from the support portion and inserted in the opening; a first bending portion extending from the support portion and bent from the support portion at a first angle; and a second bending portion extending from the first bending portion and bent from the first bending portion at a second angle; and
a cover part disposed in the insertion portion and of which at least a portion is exposed through the opening at the front surface,
wherein the first bending portion comprises: a first portion bent from the support portion; a second portion bent from the first portion; and an additional portion connected to at least one of the first portion and the second portion,
wherein a moment of inertia i of the first bending portion equals bh³/12,
where b is a thickness of the first bending portion in a thickness direction, and h is a height of the first bending portion in a height direction perpendicular to the thickness direction.

16. The window assembly of claim 15, wherein the additional portion extends from the first portion and is bent from the first portion, and
wherein the thickness b of the first bending portion is a sum of thicknesses of the first portion and the additional portion in the thickness direction.

17. The window assembly of claim 16, wherein an angle at which the additional portion is bent from the first portion is 180 degrees.

18. The window assembly of claim 15, wherein the additional portion extends from the second portion and is bent from the second portion, and
wherein the height h of the first bending portion is a height of the additional portion in the height direction.

19. The window assembly of claim 18, wherein an angle at which the additional portion is bent from the second portion is 90 degrees.

20. The window assembly of claim 15, wherein the second angle is 180 degrees, and
wherein the first angle is 90 degrees or less.

21. An assembly for supporting a cover window of a display device, the assembly comprising:
a support portion including an opening;
an insertion portion protruding from and surrounding the opening;
a first portion extending from the support portion and bent from the support portion at an acute angle;
a second portion extending from the first portion and bent from the first portion at an obtuse angle;
a third portion extending from the second portion and bent from the second portion to contact a side of the second portion;
a fourth portion extending from the third portion and bent from the third portion at an acute angle; and
a fifth portion extending from the fourth portion and bent from the fourth portion at an obtuse angle.

22. The assembly of claim 21, further comprising a mesh filling the opening.

23. The assembly of claim 21, further comprising an anti-electrostatic device connected to the fifth portion.
